(19) United States
(12) Patent Application Publication
(10) Pub. No.: US 2006/0019481 A1
(43) Pub. Date: Jan. 26, 2006

(54) GOLD BUMP STRUCTURE AND FABRICATING METHOD THEREOF

(76) Inventors: Cheng-Yi Liu, Taoyuan (TW); Shen-Jie Wang, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,087

(22) Filed: Oct. 4, 2005

Related U.S. Application Data
(62) Division of application No. 10/707,825, filed on Jan. 15, 2004.

(30) Foreign Application Priority Data
Mar. 21, 2003 (TW) 92106257

(51) Int. Cl. H01L 21/48; H01L 21/44; H01L 21/50

(52) U.S. Cl. 438/614; 438/613; 438/113; 438/108

(57) ABSTRACT

A flip-chip gold bump structure and a method of fabricating thereof are disclosed. The structure includes a nickel layer formed on a gold bump formed on a chip, and a copper layer formed on the nickel layer for forming a Ni/Cu barrier layer. Because of the formation of the Ni/Cu layer which prevents the interaction of the gold bump and the solder, the fragile connecting point resulting from the rapid interaction of the Au—Sn can be eliminated.

### CROSS-REFERENCE TO RELATED APPLICATION

This application is a divisional of a prior application Ser. No. 10/707,825, filed Jan. 15, 2004, which claims the priority benefit of Taiwan application serial no. 92106257, filed on Mar. 21, 2003.

### BACKGROUND OF THE INVENTION

1. Field of the Invention

The present invention relates to a bump structure and a fabricating method thereof, and more particularly to a gold bump structure and a fabricating method thereof.

2. Description of the Related Art

Because of the advance of semiconductor technology, electronic devices also change thereby. During forming electronic devices, the process usually includes: the formation of semiconductor substrate, the formation of semiconductor devices and package process. As to the package process, the flip-chip package process has gradually replaced the traditional package method. Because of the reduction of the signal transmission distance between the chip and substrate, the flip-chip package process has been widely used for packages of high speed devices, such as RF devices. Moreover, the process can also shrink the package size. Accordingly, it also is the most popular package technology in the near further. Generally, the flip-chip package has been applied to for example, high-speed computers, PCMCIA cards, military equipment, personal communication devices, liquid crystal displays, etc.

The bumps of the package process serve for signal connection between chips and substrates. Metal bumps, such as gold bumps, eutectic solder bumps and high lead solder bumps, have been used for the package of small devices. The gold bumps are most widely used because of their low resistance. However, because of the formation of Au—Sn composition resulting from the rapid interaction of the gold bumps and the solder, too much Au—Sn composition is formed thereat. FIG. 1 is a schematic cross-sectional figure showing a prior art flip-chip gold bump structure.

Referring to FIG. 1, a gold bump 102 is formed on a chip 100. When the gold bump 102 contacts a solder 104, a fragile Au—Sn cold joint 106 is formed at the interface thereof, which results in the reliability issue of the package. Therefore, how to prevent the rapid interaction of the gold bump and the solder is a big challenge for the gold bump application therein.

### SUMMARY OF THE INVENTION

Therefore, an object of the present invention is to provide a flip-chip gold bump structure and a fabricating method thereof for avoiding the formation of fragile Au—Sn composition resulting from the rapid interaction Au and the solder.

Another object of the present invention is to provide a flip-chip gold bump structure and a fabricating method thereof for reducing manufacturing costs and simplifying the process thereof.

The other object of the present invention is to provide a flip-chip gold bump structure and a fabricating method thereof for avoiding generating a fragile soldering point at the interface of the gold bump and the solder.

According to the objects mentioned above, the present invention discloses a flip-chip gold bump structure formed on a wafer, which comprises: a plurality of gold bumps, a nickel layer and a copper layer, wherein the nickel layer is formed on the gold bump and the copper layer is formed on the nickel layer for forming a Ni/Cu barrier layer.

The present invention also discloses a method of fabricating a flip-chip gold bump structure formed on a wafer, which comprises: forming at least one gold bump on the wafer; forming a nickel layer on the gold bump; and forming a copper layer on the nickel layer.

The present invention also discloses a flip-chip package structure adapted to connect a chip and a chip substrate, which comprises: a plurality of gold bumps, a nickel layer and a solder containing copper, wherein the nickel layer is formed on the gold bump and the solder containing copper is formed on the nickel layer for connecting the chip and the chip substrate.

The present invention further discloses a method of fabricating a flip-chip package structure adapted to connect a chip and a chip substrate, which comprises: forming at least one gold bump on a wafer; forming a nickel layer on the gold bump; sawing the wafer; forming a solder containing copper on the chip substrate; aligning the gold bump to the solder containing copper; and performing a reflow process.

The present invention uses a Ni/Cu layer on the gold bump for forming Cu—Ni—Sn composition at the interface of the gold bump structure and the solder instead of the traditional AuSn₄ composition. Therefore, the present invention can resolve the issue deriving from the rapid interaction of gold bump structure and the solder.

In order to make the aforementioned and other objects, features and advantages of the present invention understandable, a preferred embodiment accompanied with figures is described in detail below.

### BRIEF DESCRIPTION OF THE DRAWINGS

FIG. 1 is a schematic cross-sectional figure showing a prior art flip-chip gold bump structure.

FIG. 2 is a schematic cross-sectional view showing a first exemplary gold bump structure of the present invention.

FIG. 3 is a schematic process flow showing the method of fabricating the flip-chip gold bump structure of FIG. 2.

FIG. 4 is a schematic cross-sectional view showing a second exemplary flip-chip package of the present invention.

FIG. 5 is a schematic process flow showing the method of fabricating the flip-chip package of FIG. 4.

### DESCRIPTION OF PREFERRED EMBODIMENTS

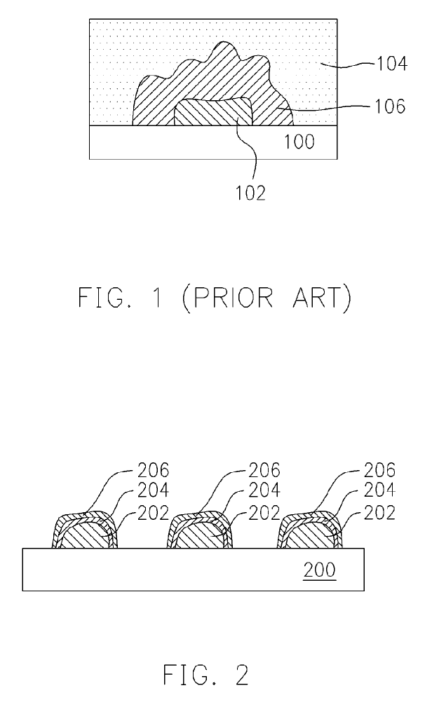

FIG. 2 is a schematic cross-sectional view showing a first exemplary gold bump structure of the present invention.

Referring to FIG. 2, the flip-chip gold bump structure of the present invention formed on a wafer 200, which comprises: gold bumps 202, a nickel layer 204 and the copper layer 206, wherein the gold bump has a height about from 3 μm to about 150 μm. The nickel layer 204 is formed on the gold bump 202 and has a thickness about from 0.1 μm to about 20 μm. The copper layer 206 is formed on the nickel layer 204 and has a thickness about from 0.1 μm to about 10 μm.

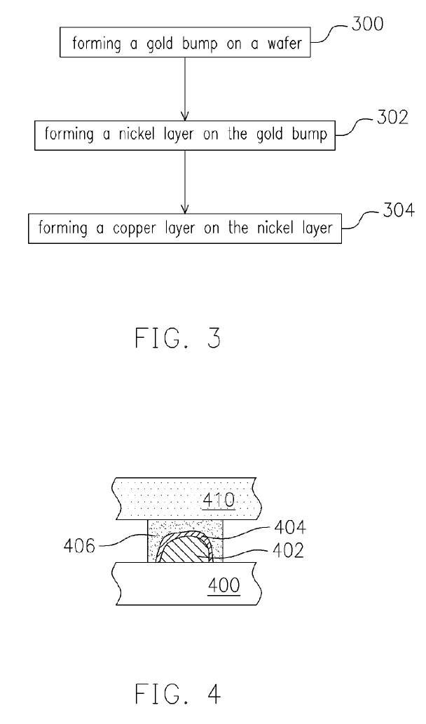

FIG. 3 is a schematic process flow showing the method of fabricating the flip-chip gold bump structure of FIG. 2. Referring to FIG. 3, in step 300, the step of forming the gold bump on the wafer includes electroplating or electroless plating. In step 302, the step of forming the nickel layer on the gold bump includes electroplating or electroless plating. In step 304, the step of forming the copper layer on the nickel layer includes electroplating or electroless plating.

When the flip-chip gold bump structure of the present invention is applied to the flip-chip package, because of the formation of the Ni/Cu barrier layer on the gold bump, AuSn₄ composition generated from the rapid interaction between Au and Sn can be substantially reduced and Cu—Ni—Sn composition is the prior product having a slow growth rate is generated thereat. Therefore, the present invention can resolve the issue resulting from the rapid interaction between the flip-chip gold bump structure and the solder.

FIG. 4 is a schematic cross-sectional view showing a second exemplary flip-chip package of the present invention.

The flip-chip package of the present invention formed between a chip 400 and a chip substrate 410, which comprises: gold bumps 402, a nickel layer 404 and a solder containing copper 406, wherein the gold bump has a height about from 3 μm to about 150 μm and the solder containing copper can be a solder alloy and have copper from about 0.7 wt. % to about 3.0 wt. %. The nickel layer 404 is formed on the gold bump 402 and has a thickness about from 0.1 μm to about 20 μm. The solder containing copper 406 is formed on the chip substrate 410 for connecting the chip 400 and chip substrate 410.

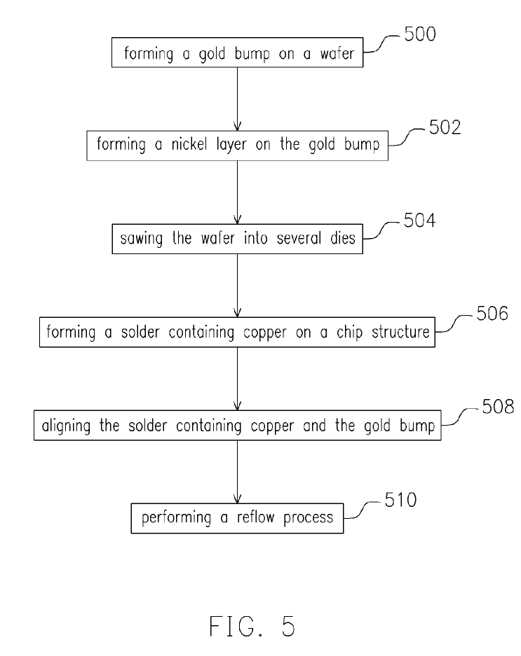

FIG. 5 is a schematic process flow showing the method of fabricating the flip-chip package of FIG. 4. Referring to FIG. 5, in step 500, the step of forming the gold bump on the wafer includes electroplating or electroless plating. In step 502, the step of forming the nickel layer on the gold bump includes electroplating or electroless plating. In step 504, the wafer is sawed into several dies. In step 506, the solder containing copper, which can be a solder alloy and have copper from about 0.7 wt. % to about 3.0 wt. % is formed on the chip substrate. In step 508, the gold bump is aligned to the solder containing copper for connecting thereof. In step 510, a reflow process is performed.

When the present invention is applied to the flip-chip package, Cu—Ni—Sn composition is formed at the interface of the gold bump structure and the solder during the reflow process instead of the traditional AuSn₄ composition. Therefore, the present invention can resolve the issue deriving from the rapid interaction of gold bump structure and the solder.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A method of fabricating a flip-chip gold bump structure formed on a wafer, comprising:
forming at least one gold bump on the wafer;
forming a nickel layer on the gold bump; and
forming a copper layer on the nickel layer.

2. The method of fabricating a flip-chip gold bump structure of claim 1, wherein the step of forming the gold bump includes electroplating.

3. The method of fabricating a flip-chip gold bump structure of claim 1, wherein the step of forming the gold bump includes electroless plating.

4. The method of fabricating a flip-chip gold bump structure of claim 1, wherein the step of forming the nickel layer on the gold bump includes electroplating.

5. The method of fabricating a flip-chip gold bump structure of claim 1, wherein the step of forming the nickel layer on the gold bump includes electroless plating.

6. The method of fabricating a flip-chip gold bump structure of claim 1, wherein the step of forming the copper layer on the nickel layer includes electroplating.

7. The method of fabricating a flip-chip gold bump structure of claim 1, wherein the step of forming the copper layer on the nickel layer includes electroless plating.

8. A method of fabricating a flip-chip package adapted to connect a chip and a chip substrate, comprising:
forming at least one gold bump on a wafer;
forming a nickel layer on the gold bump;
sawing the wafer;
forming a solder containing copper on the chip substrate; and
aligning the gold bump to the solder containing copper.

9. The method of fabricating a flip-chip package of claim 8, wherein the step of forming the gold bump on the wafer includes electroplating.

10. The method of fabricating a flip-chip package of claim 8, wherein the step of forming the gold bump on the wafer includes electroless plating.

11. The method of fabricating a flip-chip gold bump structure of claim 8, wherein the step of forming the nickel layer on the gold bump includes electroplating.

12. The method of fabricating a flip-chip gold bump structure of claim 8, wherein the step of forming the nickel layer on the gold bump includes electroless plating.

13. The method of fabricating a flip-chip gold bump structure of claim 8, further comprising a reflow process after aligning the gold bump to the solder containing copper.
